(19) United States
(12) Patent Application Publication
(10) Pub. No.: US 2022/0085061 A1
(43) Pub. Date: Mar. 17, 2022

(54) SEMICONDUCTOR DEVICE AND METHOD OF MANUFACTURING SAME

(71) Applicant: Kioxia Corporation, Tokyo (JP)

(72) Inventor: Shuto YAMASAKA, Yokkaichi (JP)

(73) Assignee: Kioxia Corporation, Tokyo (JP)

(21) Appl. No.: 17/196,141

(22) Filed: Mar. 9, 2021

(30) Foreign Application Priority Data
Sep. 14, 2020 (JP) 2020-154035

(51) Int. Cl. H01L 27/11582; H01L 27/11556; H01L 25/00; H01L 25/18

(52) U.S. Cl. CPC H01L 27/11582; H01L 27/11556; H01L 24/08; H01L 25/18; H01L 25/50

(57) ABSTRACT

In one embodiment, a semiconductor device includes a substrate, and a stacked film including a plurality of electrode layers and a plurality of insulating layers alternately provided above the substrate. The device further includes a first semiconductor layer provided in the stacked film, and a second semiconductor layer provided on the first semiconductor layer in the stacked film, and including a monocrystalline semiconductor layer. The device further includes an interconnect layer provided on the stacked film and the second semiconductor layer, and electrically connected to the second semiconductor layer.

### CROSS REFERENCE TO RELATED APPLICATION

This application is based upon and claims the benefit of priority from the prior Japanese Patent Application No. 2020-154035, filed on Sep. 14, 2020, the entire contents of which are incorporated herein by reference.

### FIELD

Embodiments described herein relate to a semiconductor device and a method of manufacturing the same.

### BACKGROUND

In a semiconductor memory such as a 3D memory, it is desirable to enhance performance of a semiconductor layer such as a channel semiconductor layer.

### BRIEF DESCRIPTION OF THE DRAWINGS

FIG. 1 is a sectional view illustrating a structure of a semiconductor device of a first embodiment;

FIG. 2 is an enlarged sectional view illustrating a structure of a columnar portion of the first embodiment;

FIG. 3 is an enlarged sectional view illustrating the structure of the semiconductor device of the first embodiment;

FIG. 4 is an enlarged sectional view illustrating a structure of a semiconductor device of a comparative example for the first embodiment;

FIGS. 5A to 10B are sectional views illustrating a method of manufacturing the semiconductor device of the first embodiment;

FIGS. 11A and 11B are sectional views illustrating a method of manufacturing a semiconductor device of a modification of the first embodiment; and

FIG. 12 is a sectional view illustrating an overall structure of the semiconductor device of the first embodiment.

### DETAILED DESCRIPTION

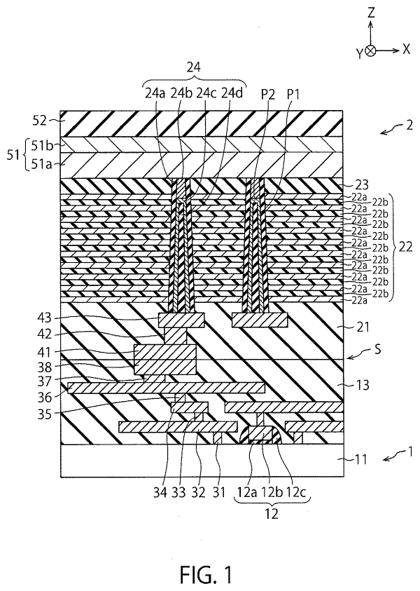

Embodiments will now be explained with reference to the accompanying drawings. In FIGS. 1 to 12, components that are identical to each other are provided with a same sign and overlapping description thereof will be omitted.

In one embodiment, a semiconductor device includes a substrate, and a stacked film including a plurality of electrode layers and a plurality of insulating layers alternately provided above the substrate. The device further includes a first semiconductor layer provided in the stacked film, and a second semiconductor layer provided on the first semiconductor layer in the stacked film, and including a monocrystalline semiconductor layer. The device further includes an interconnect layer provided on the stacked film and the second semiconductor layer, and electrically connected to the second semiconductor layer.

### First Embodiment

FIG. 1 is a view illustrating a structure of a semiconductor device of a first embodiment.

The semiconductor device of the present embodiment is, for example, a 3D memory, and includes a circuit region 1 and an array region 2 provided on the circuit region 1. As described later, for example, the semiconductor device of the present embodiment is manufactured by bonding a circuit wafer including the circuit region 1 and an array wafer including the array region 2. FIG. 1 illustrates a bonding face S between the circuit region 1 (circuit wafer) and the array region 2 (array wafer).

The semiconductor device of the present embodiment includes a substrate 11, a transistor 12 and an inter layer dielectric 13 in the circuit region 1 and includes an inter layer dielectric 21, a stacked film 22, an inter layer dielectric 23 and a plurality of columnar portions 24 in the array region 2. The transistor 12 includes a gate insulator 12a, a gate electrode 12b and an insulator 12c. The stacked film 22 includes a plurality of electrode layers 22a and a plurality of insulating layers 22b. Each columnar portion 24 includes a memory insulator 24a, a semiconductor layer 24b, a channel semiconductor layer 24c and a core insulator 24d. The channel semiconductor layer 24c is an example of “first semiconductor layer” and the semiconductor layer 24b is an example of “second semiconductor layer”.

The semiconductor device of the present embodiment further includes a contact plug 31, an interconnect layer 32 including one or more interconnects, a via plug 33, an interconnect layer 34 including one or more interconnects, a via plug 35, an interconnect layer 36 including one or more interconnects, a via plug 37 and a metal pad 38 in the circuit region 1 and includes a metal pad 41, a via plug 42, an interconnect layer 43 including one or more interconnects, an interconnect layer 51 and a passivation film 52 in the array region 2. The interconnect layer 51 includes a semiconductor layer 51a and a metal layer 51b. The semiconductor layer 51a is an example of “third semiconductor layer”.

In FIG. 1, an X-direction, a Y-direction and a Z-direction perpendicular to one another are indicated. In this specification, a +Z-direction is regarded as an upward direction and a −Z-direction is regarded as a downward direction. The −Z-direction may coincide with the gravity direction or may not coincide with the gravity direction. The Z-direction is an example of “first direction”.

The substrate 11 is, for example, a semiconductor substrate such as a silicon substrate. The transistor 12 includes a gate insulator 12a formed on the substrate 11, a gate electrode 12b provided on the gate insulator 12a and a insulator 12c provided on side faces of the gate electrode 12b. The semiconductor device of the present embodiment includes a plurality of transistors 12 on the substrate 11, and FIG. 1 illustrates one of the transistors 12. The transistors 12 form, for example, a control circuit (logic circuit) that controls operation of the semiconductor device of the present embodiment. The inter layer dielectric 13 is formed on the substrate 11 to cover the transistors 12.

The inter layer dielectric 21 is formed on the inter layer dielectric 13. The stacked film 22 includes the plurality of electrode layers 22a and the plurality of insulating layer 22b that are alternately stacked on the inter layer dielectric 21. As described later, the electrode layers 22a of the present embodiment include a plurality of word lines, one or more source-side select lines and one or more drain-side select lines. Each electrode layer 22a includes, for example, a metal layer such as a W (tungsten) layer. Each insulating layer 22b is, for example, a silicon oxide film. The inter layer dielectric 23 is formed on the stacked film 22.

Each columnar portion 24 has a columnar shape extending in the Z direction and is formed in the inter layer dielectric 21, the stacked film 22 and the inter layer dielectric 23. Each columnar portion 24 includes a memory insulator 24a formed on respective side faces of the inter layer dielectric 21, the stacked film 22 and the inter layer dielectric 23, a semiconductor layer 24b and a channel semiconductor layer 24c each formed on a side face of the memory insulator 24a, and a core insulator 24d formed on a side face of the channel semiconductor layer 24c.

The memory insulator 24a includes a tubular shape extending in the Z-direction and surrounds the semiconductor layer 24b and the channel semiconductor layer 24c. As described later, the memory insulator 24a includes a block insulator, a charge storage layer and a tunnel insulator.

The channel semiconductor layer 24c has a tubular shape extending in the Z direction and surrounds the core insulator 24d. More specifically, the channel semiconductor layer 24c includes a side portion P1 having a tubular shape extending in the Z-direction, and a bottom portion P2 having a bottom shape provided on an upper end of the tubular shape of the side portion P1. The channel semiconductor layer 24c is, for example, a polycrystalline semiconductor layer such as a polycrystalline silicon (polysilicon) layer. The side portion P1 is an example of “first portion” and the bottom portion P2 is an example of “second portion”. The channel semiconductor layer 24c may include n-type impurity atoms or p-type impurity atoms or may include neither n-type impurity atoms nor p-type impurity atoms.

The semiconductor layer 24b has a non-tubular shape extending in the Z-direction and is formed on the bottom portion P2 of the channel semiconductor layer 24c. While the side portion P1 of the channel semiconductor layer 24c has a tubular shape, that is, a hollow columnar shape, the semiconductor layer 24b has a non-tubular shape, that is, a solid columnar shape. The semiconductor layer 24b is, for example, a monocrystalline semiconductor layer such as a monocrystalline silicon (mono-silicon) layer. The semiconductor layer 24b of the present embodiment includes an upper face at a same level as an upper face of the inter layer dielectric 23 and includes a lower face at a level that is lower than a lower face of the inter layer dielectric 23. Details of the level of the lower face of the semiconductor layer 24b of the present embodiment will be described later.

The semiconductor layer 24b includes, for example, n-type impurity atoms or p-type impurity atoms. A density of the n-type impurity atoms or the p-type impurity atoms in the semiconductor layer 24b is, for example, 1.0×10¹⁹ cm⁻³ or more. The semiconductor layer 24b of the present embodiment includes P (phosphorus) atoms with a density of 1.0×10¹⁹ cm⁻³ to 5.0×10¹⁹ cm⁻³.

The core insulator 24d has a non-tubular shape extending in the Z-direction and is formed in the side portion P1 of the channel semiconductor layer 24c. The core insulator 24d is, for example, a silicon oxide film.

In each columnar portion 24, a plurality of memory cell transistors and a plurality of select transistors are formed by the memory insulator 24a, the semiconductor layer 24b, the channel semiconductor layer 24c and the core insulator 24d. The memory cell transistors and the select transistors form a memory cell array for a 3D memory.

The contact plug 31, the interconnect layer 32, the via plug 33, the interconnect layer 34, the via plug 35, the interconnect layer 36, the via plug 37, the metal pad 38, the metal pad 41, the via plug 42 and the interconnect layer 43 are provided in the order mentioned in the inter layer dielectrics 13, 21 on the substrate 11. The semiconductor device of the present embodiment includes a plurality of contact plugs 31, a plurality of via plugs 33, a plurality of via plugs 35, a plurality of via plugs 37, a plurality of metal pads 38, a plurality of metal pads 41 and a plurality of via plugs 42, and FIG. 1 illustrates some of the plugs and the pads. The above control circuit is electrically connected to the memory cell array via the plugs, the pads and the interconnect layers and controls operation of the memory cell array via the plugs, the pads and the interconnect layers.

Each of the metal pads 38, 41 includes, for example, a metal layer such as a Cu (copper) layer. In the semiconductor device of the present embodiment, the metal pads 38 and the metal pads 41 are joined to each other and the inter layer dielectric 13 and the inter layer dielectric 21 are bonded to each other. In the present embodiment, each columnar portion 24 is formed on the interconnect layer 43, and consequently, the channel semiconductor layer 24c of each columnar portion 24 is electrically connected to the interconnect layer 43.

The interconnect layer 51 includes a semiconductor layer 51a formed on the inter layer dielectric 23 and the columnar portions 24 and a metal layer 51b formed on the semiconductor layer 51a. In the present embodiment, the semiconductor layer 51a is in contact with the semiconductor layer 24b of each columnar portion 24, and consequently, the interconnect layer 51 is electrically connected to the semiconductor layer 24b of each columnar portion 24. The semiconductor layer 51a is, for example, a P atom-doped polysilicon layer.

The passivation film 52 is formed on the interconnect layer 51. The passivation film 52 is, for example, an insulator such as a silicon oxide film. The passivation film 52 may include a silicon oxide film and another insulator.

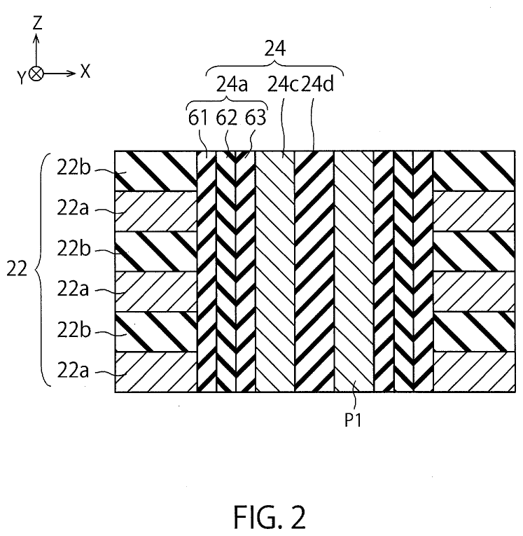

FIG. 2 is an enlarged sectional view illustrating a structure of a columnar portion 24 of the first embodiment.

As illustrated in FIG. 2, the columnar portion 24 includes a memory insulator 24a, a channel semiconductor layer 24c (side portion P1) and a core insulator 24d formed in the order mentioned, in the stacked film 22. The memory insulator 24a includes a block insulator 61, a charge storage layer 62 and a tunnel insulator 63 formed in the order mentioned, in the stacked film 22.

The block insulator 61 is, for example, a silicon oxide film. The charge storage layer 62 is, for example, an insulator such as a silicon nitride film and has a function that stores signal charges. The charge storage layer 62 may be a semiconductor layer such as a polysilicon layer. The tunnel insulator 63 is, for example, a silicon oxide film. Each of the block insulator 61, the charge storage layer 62 and the tunnel insulator 63 has a tubular shape extending in the Z-direction and surrounds the channel semiconductor layer 24c and the semiconductor layer 24b (see FIG. 1).

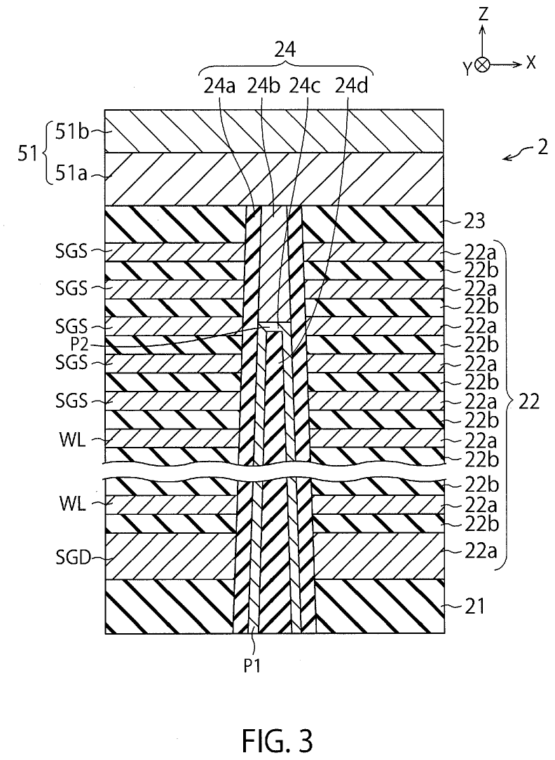

FIG. 3 is an enlarged sectional view illustrating a structure of the semiconductor device of the first embodiment.

FIG. 3 illustrates the stacked film 22 including the plurality of electrode layers 22a and the plurality of insulating layers 22b alternately, and a columnar portion 24 provided in the stacked film 22. The electrode layers 22a include one or more drain-side select lines SGD, a plurality of word lines WL provided above the one or more drain-side select lines SGD, and one or more source-side select lines SGS provided above the word lines WL. Although the electrode layers 22a illustrated in FIG. 3 include, as an example, one drain-side select line SGD and five source-side select lines SGS, the number of drain-side select lines SGD and the number of source-side select lines SGS are not limited to this example. The drain-side select line SGD is an example of “first select line” and the source-side select line SGS is an example of “second select line”.

The semiconductor layer 24b of the present embodiment includes an upper face at a same level as the upper face of the inter layer dielectric 23 and includes a lower face at a level that is lower than the lower face of the inter layer dielectric 23. For example, the lower face of the semiconductor layer 24b illustrated in FIG. 3 is located at a level that is between a lower face of the lowermost source-side select line SGS and an upper face of the uppermost source-side select line SGS, and here, is located at a level that is between a lower face and an upper face of the third source-side select line SGS from the bottom (i.e., the third from the top).

In the semiconductor device of the present embodiment, when data stored in memory cells in a certain columnar portion 24 (NAND string) are erased, an erasing voltage is applied to predetermined source-side select lines SGS of the columnar portion 24. Consequently, a gate induced drain leakage (GIDL) current is generated in predetermined select transistors in the columnar portion 24 and flows to the memory cells. The data stored in the memory cells are erased by the GIDL current.

The predetermined source-side select lines SGS of the present embodiment are source-side select lines SGS facing the semiconductor layer 24b, more specifically, the first (uppermost) source-side select line SGS from the top, a second source-side select line SGS from the top and the third source-side select line SGS from the top. Upon an erasing voltage being applied to these source-side select lines SGS, a GIDL current is generated in the select transistors corresponding to these source-side select lines SGS, and for more detail, a GIDL current is generated in the semiconductor layer 24b. These source-side select lines SGS are called GIDL generators.

The semiconductor layer 24b of the present embodiment is provided to promote generation of the GIDL current. Therefore, as described above, P atoms with a high density are included in the semiconductor layer 24b. The present embodiment makes it possible to effectively generate a GIDL current by setting the semiconductor layer 24b as channel regions of the select transistors corresponding to the predetermined source-side select lines SGS (GIDL generators).

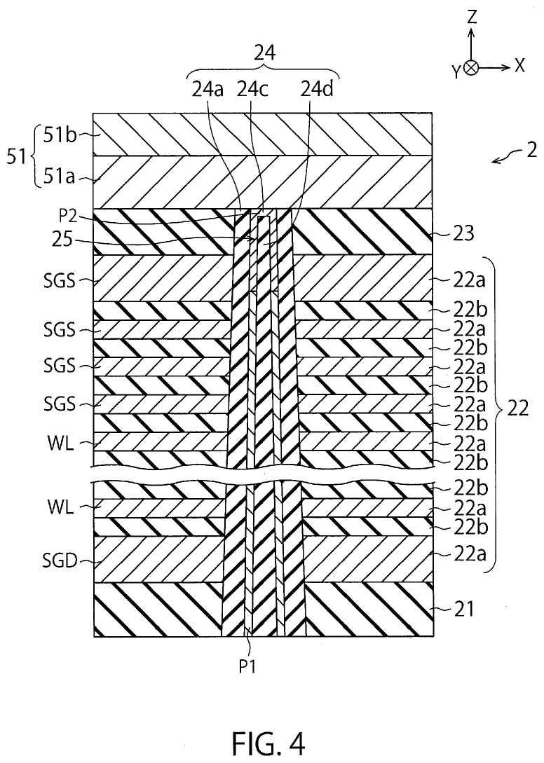

FIG. 4 is an enlarged sectional view illustrating a structure of a semiconductor device of a comparative example for the first embodiment.

FIG. 4 illustrates a stacked film 22 including a plurality of electrode layers 22a and a plurality of insulating layers 22b alternately and a columnar portion 24 provided in the stacked film 22. The electrode layers 22a include one or more drain-side select lines SGD, a plurality of word lines WL disposed above the one or more drain-side select lines SGD, and one or more source-side select lines SGS provided above the word lines WL. The electrode layers 22a illustrated in FIG. 4 include, as an example, one drain-side select line SGD and four source-side select lines SGS.

The columnar portion 24 of the present comparative example includes no semiconductor layer 24b. Therefore, in a channel semiconductor layer 24c of the present comparative example, a side portion P1 extends to a lower face of an interconnect layer 51 and a bottom portion P2 is in contact with the lower face of the interconnect layer 51.

The columnar portion 24 of the present comparative example includes an impurity diffusion layer 25 provided in the channel semiconductor layer 24c, instead of the semiconductor layer 24b. The impurity diffusion layer 25 is, for example, a P atom-doped polysilicon layer. In the present comparative example, a source-side select line SGS facing the impurity diffusion layer 25, that is, an uppermost source-side select line SGS functions as a GIDL generator. In the present comparative example, a GIDL current is generated in the impurity diffusion layer 25.

Here, the semiconductor device of the first embodiment illustrated in FIG. 3 and the semiconductor device of the comparative example illustrated in FIG. 4 are compared.

In the comparative example illustrated in FIG. 4, for example, the impurity diffusion layer 25 is formed by injecting P atoms into the channel semiconductor layer 24c. In this case, a position at which the impurity diffusion layer 25 is formed changes according to a position at which the P atoms are injected. In general, since it is desirable to bring values of GIDL currents generated by different columnar portions 24 close to a same value, it is desirable to bring positions of impurity diffusion layers 25 in different columnar portions 24 close to a same position. However, since, in general, a position at which P atoms are injected varies between different impurity diffusion layers 25, it is difficult to bring positions of impurity diffusion layers 25 of different columnar portions 24 close to a same position. Furthermore, when the P atoms injected in the channel semiconductor layers 24c are diffused by annealing, the positions of the P atoms may further vary.

On the other hand, in the first embodiment illustrated in FIG. 3, not the impurity diffusion layer 25 formed in the channel semiconductor layer 24c but the semiconductor layer 24b formed separately from the channel semiconductor layer 24c is used to generate a GIDL current. Therefore, the present embodiment makes it possible to easily bring positions of semiconductor layers 24b of different columnar portions 24 close to a same position, which makes it possible to easily bring values of GIDL currents generated in the different columnar portions 24 close to a same value. As described later, since the semiconductor layer 24b of the present embodiment is formed by epitaxial growth, it is easy to bring positions of semiconductor layers 24b of different columnar portions 24 close to a same position.

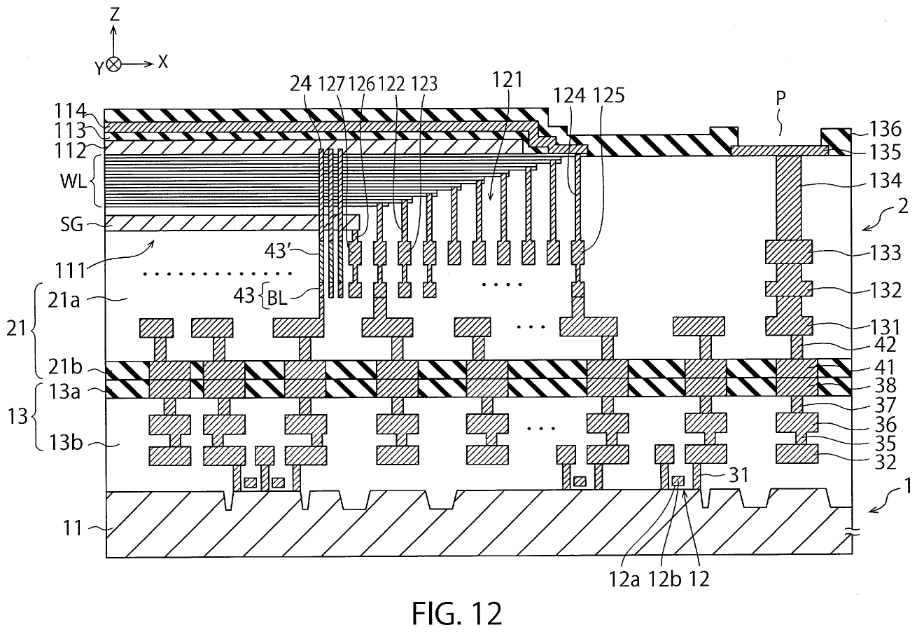

FIG. 12 is a sectional view illustrating an overall structure of the semiconductor device of the first embodiment.

The array region 2 includes a memory cell array 111 including a plurality of memory cells, a semiconductor layer 112 on the memory cell array 111, a back-gate insulator 113 on the semiconductor layer 112, and a back-gate electrode 114 on the back-gate insulator 113. The back-gate electrode 114 is used for controlling electric fields of the semiconductor layer 112 like a selection gate SG to be descried later. The array region 2 further includes, as the inter layer dielectric 21, an inter layer dielectric 21a under the memory cell array 111 and an insulator 21b under the inter layer dielectric 21a. The insulator 21b is a silicon oxide film, for example.

The circuit region 1 is provided under the array region 2. The circuit region 1 includes, as the inter layer dielectric 13, an insulator 13a under the insulator 21b, an inter layer dielectric 13b under the insulator 13a, and the substrate 11 under the inter layer dielectric 13b. The insulator 13a is a silicon oxide film, for example. The substrate 11 is a semiconductor substrate such as a silicon substrate, for example.

The array region 2 includes a plurality of word lines WL and a selection gate SG as electrode layers in the memory cell array 111. FIG. 12 illustrates a step-like structure portion 121 of the memory cell array 111. The array region 2 further includes the above-described back-gate electrode 114 as an electrode layer outside the memory cell array 111. As illustrated in FIG. 12, each of the word lines WL is electrically connected to a word interconnect layer 123 via a contact plug 122, the back-gate electrode 114 is electrically connected to a back-gate interconnect layer 125 via a contact plug 124, and the selection gate SG is electrically connected to a selection gate interconnect layer 127 via a contact plug 126. A columnar portion 24 piercing through the word lines WL and the selection gate SG is electrically connected to a bit line BL in the interconnect layer 43 via the contact plug 43′ and electrically connected to the semiconductor layer 112 as well. The word lines WL are examples of the electrode layers 22a described above.

The circuit region 1 includes a plurality of transistors 12. Each of the transistors 12 includes a gate electrode 12b provided on the substrate 11 via a gate insulator 12a, and a source diffusion layer as well as a drain diffusion layer, not shown, provided in the substrate 11. The circuit region 1 further includes a plurality of contact plugs 31 provided on the source diffusion layer or the drain diffusion layer of those transistors 12, an interconnect layer 32 including a plurality of interconnects provided on those contact plugs 14, and via plugs 35 provided on the interconnect layer 32. The circuit region 1 further includes an interconnect layer 36 including a plurality of interconnects provided on the via plugs 35, a plurality of via plugs 37 provided on the interconnect layer 36, and a plurality of metal pads 38 provided on the via plugs 37 in the insulator 13a. It is noted that illustrations of the above mentioned via plugs 33 and interconnect layer 34 are omitted. The circuit region 1 functions as a control circuit (logic circuit) that controls the array region 2.

The array region 2 includes a plurality of metal pads 41 provided on the metal pads 38 in the insulator 21b, a plurality of via plugs 42 provided on the metal pads 41, and an interconnect layer 131 including a plurality of interconnects provided on those via plugs 42. Each of the word lines WL and each of the bit lines BL are electrically connected to the corresponding lines in the interconnect layer 131. The array region 2 further includes an interconnect layer 132 including a plurality of interconnects provided on the interconnect layer 131, an interconnect layer 133 including a plurality of interconnects provided on the interconnect layer 132, and a via plug 134 provided on the interconnect layer 133. The array region 2 further includes a metal pad 135 provided on the via plug 134, and a passivation film 136 that covers the metal pad 135 and the back-gate electrode 114. The passivation film 136 is a silicon oxide film, for example, and includes an opening portion P for exposing the top face of the metal pad 135. The metal pad 135 is an external connection pad of the semiconductor device illustrated in FIG. 12, and can be connected to a mounting board or another device via solder balls, metal bumps, wire bonding, or the like.

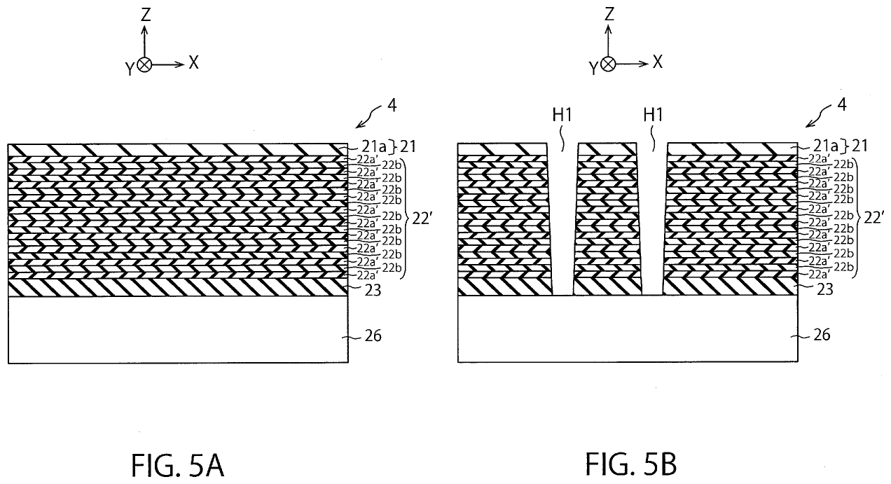

FIGS. 5A to 10B are sectional views illustrating a method of manufacturing the semiconductor device of the first embodiment.

First, a substrate 26 for an array wafer 4 is provided, and an inter layer dielectric 23, a stacked film 22′ and an insulator 21a that is a portion of an inter layer dielectric 21 are sequentially formed on the substrate 26 (FIG. 5A). The substrate 26 is, for example, a semiconductor substrate such as a silicon substrate. The stacked film 22′ is formed to include a plurality of sacrifice layers 22a′ and a plurality of insulating layers 22b alternately. Each sacrifice layer 22a′ is, for example, a silicon nitride film. The substrate 26 is an example of “first substrate”. Each sacrifice layers 22a′ is an example of “first film” and each insulating layers 22b is an example of “second film”.

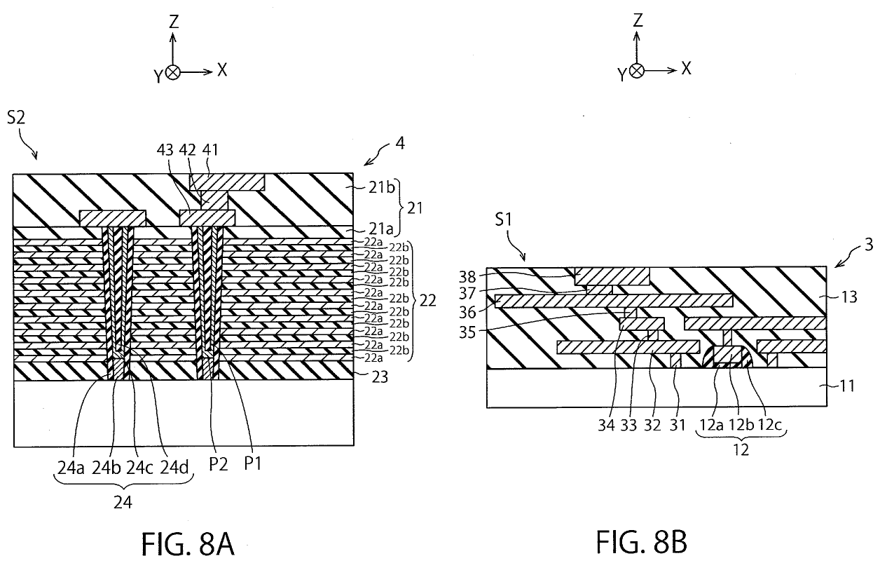

The sacrifice layers 22a′ are replaced with a plurality of electrode layers 22a in a later-described step (step in FIG. 8A). Consequently, a stacked film 22 including the plurality of electrode layers 22a and the plurality of insulating layers 22b alternately is formed between the inter layer dielectric 23 and the insulator 21a.

Next, a plurality of memory holes H1 are formed in the insulator 21a, the stacked film 22′ and the inter layer dielectric 23 (FIG. 5B). As a result, an upper face of the substrate 26 is exposed in the memory holes H1. Each memory hole H1 is an example of “concave portion”.

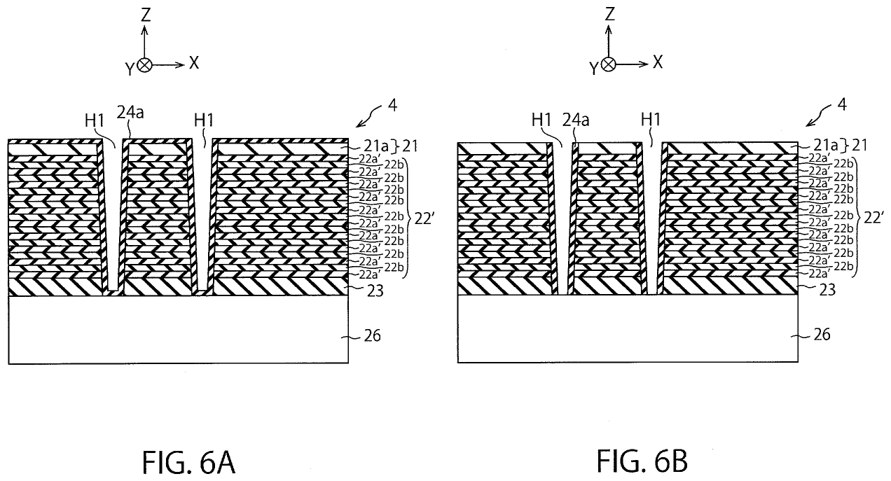

Next, a memory insulator 24a is formed on all surfaces of the substrate 26 (FIG. 6A). As a result, the memory insulator 24a is formed on the upper face of the substrate 26 in the memory holes H1, respective side faces of the insulator 21a, the stacked film 22′ and the inter layer dielectric 23 in the memory holes H1 and an upper face of the insulator 21a outside the memory holes H1. The memory insulator 24a is formed by forming a block insulator 61, a charge storage layer 62 and a tunnel insulator 63 (FIG. 2) sequentially on all the surfaces of the substrate 26.

Next, the memory insulator 24a is removed from the upper face of the substrate 26 in the memory holes H1 and the upper face of the insulator 21a outside the memory holes H1 by dry etching (FIG. 6B). As a result, the upper face of the substrate 26 is exposed again in the memory holes H1. In this way, the memory insulator 24a is processed to have a tubular shape extending in the Z-direction.

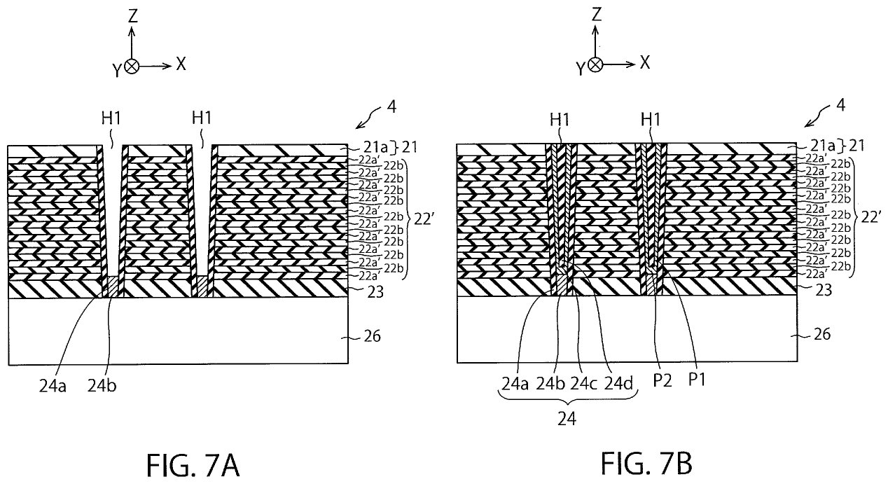

Next, a semiconductor layer 24b is formed on the upper face of the substrate 26 in the memory holes H1 by epitaxial growth from the substrate 26 (FIG. 7A). The semiconductor layer 24b is, for example, a P atom-doped monocrystalline silicon layer. A density of P atoms in the semiconductor layer 24b is, for example, 1.0×10¹⁹ cm⁻³ or more, preferably, 1.0×10¹⁹ cm⁻³ to 5.0×10¹⁹ cm⁻³. In this way, the semiconductor layer 24b is processed to have a non-tubular shape extending in the Z-direction.

A vertical direction of the array wafer 4 illustrated in FIG. 7A is opposite to a vertical direction of the array region 2 illustrated in FIG. 3. Therefore, an upper face of the semiconductor layer 24b illustrated in FIG. 7A corresponds to the lower face of the semiconductor layer 24b illustrated in FIG. 3. In the step in FIG. 7A, the semiconductor layer 24b is formed such that a position of the upper face of the semiconductor layer 24b is located at the position of the lower face of the semiconductor layer 24b illustrated in FIG. 3. Therefore, the upper face of the semiconductor layer 24b illustrated in FIG. 7A is located at a level that is between an upper face of an uppermost (lowermost in FIG. 3) source-side select line SGS and a lower face of a lowermost (uppermost in FIG. 3) source-side select line SGS. However, at the stage illustrated in FIG. 7A, since the sacrifice layers 22a′ have not yet been replaced with the electrode layers 22a, more exactly, the upper face of the semiconductor layer 24b illustrated in FIG. 7A is located at a level that is between an upper face of a sacrifice layer 22a′ corresponding to the uppermost source-side select line SGS and a lower face of a sacrifice layer 22a′ corresponding to the lowermost source-side select line SGS.

Next, a channel semiconductor layer 24c and a core insulator 24d are sequentially formed on all the surfaces of the substrate 26 and the channel semiconductor layer 24c and the core insulator 24d outside the memory holes H1 are removed (FIG. 7B). As a result, the channel semiconductor layer 24c is formed on the upper face of the semiconductor layer 24b in the memory holes H1 and the respective side faces of the stacked film 22′ and the inter layer dielectric 23 in the memory holes H1. Furthermore, the core insulator 24d is formed on an upper face and a side face of the channel semiconductor layer 24c in the memory holes H1. In this way, the channel semiconductor layer 24c is formed to have a tubular shape extending in the Z-direction and the core insulator 24d is formed to have a non-tubular shape extending in the Z-direction. More specifically, the channel semiconductor layer 24c is formed to include a side portion P1 having a tubular shape extending in the Z-direction, and a bottom portion P2 having a bottom shape provided on a lower end of the tubular shape of the side portion P1. In this way, a plurality of columnar portions 24 are formed in the plurality of memory holes H1.

Next, the sacrifice layers 22a′ are replaced with the electrode layers 22a (FIG. 8A). More specifically, a slit is formed in the insulator 21a and the stacked film 22′, and the sacrifice layers 22a′ are removed by wet etching using the slit, and the plurality of electrode layers 22a are embedded into a plurality of concave portions formed by the removal of the sacrifice layers 22a′. As a result, the stacked film 22 including the plurality of electrode layers 22a and the plurality of insulating layers 22b alternately is formed between the inter layer dielectric 23 and the insulator 21a. The electrode layers 22a include, for example, a plurality of word lines WL, one or more source-side select lines SGS and one or more drain-side select lines SGD (see FIG. 3).

In the step in FIG. 5A, instead of forming the stacked film 22′ including the plurality of sacrifice layers 22a′ and the plurality of insulating layers 22b alternately, a stacked film 22 including a plurality of electrode layers 22a and a plurality of insulating layers 22b alternately may be formed. In this case, in the step in FIG. 8A, there is no need to replace the sacrifice layers 22a′ with the electrode layers 22a. Each electrode layer 22a and each insulating layer 22b in this case are respective examples of “first film” and “second film”.

Next, an insulator 21b that is a portion of the inter layer dielectric 21, an interconnect layer 43, via plugs 42 and metal pads 41 are formed on the insulator 21a and the respective columnar portions 24 (FIG. 8A). In this way, the array wafer 4 to be bonded is manufactured. FIG. 8A illustrates an upper face S2 of the array wafer 4, which becomes a bonding face S of the array wafer 4.

Next, a substrate 11 for a circuit wafer 3 is provided, and transistors 12, an inter layer dielectric 13, contact plugs 31, an interconnect layer 32, via plugs 33, an interconnect layer 34, via plugs 35, an interconnect layer 36, via plugs 37 and metal pads 38 are formed on the substrate 11 (FIG. 8B). In this way, the circuit wafer 3 to be bonded is manufactured. FIG. 8B illustrates an upper face S1 of the circuit wafer 3, which becomes a bonding face S of the circuit wafer 3.

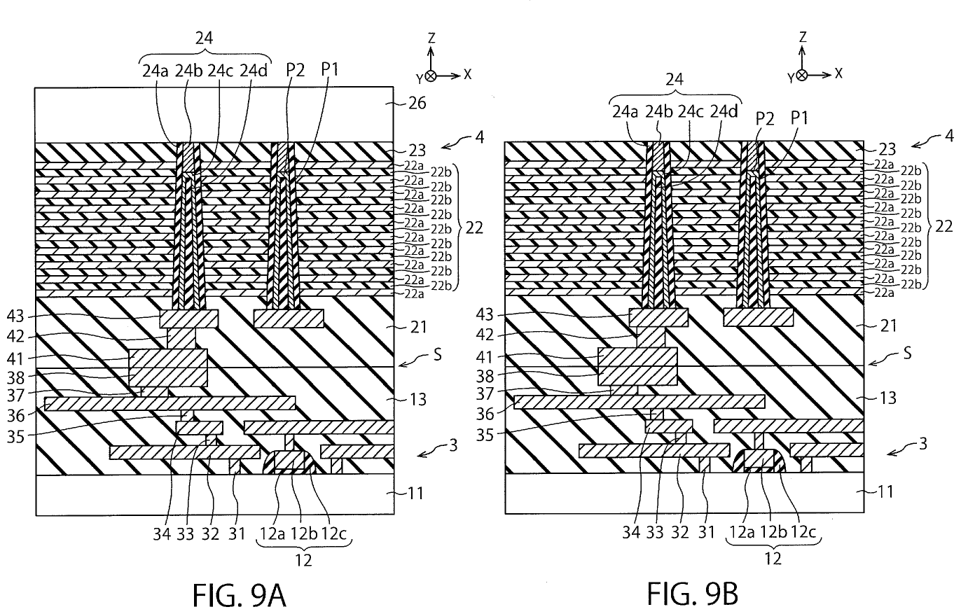

Next, the array wafer 4 is disposed on the circuit wafer 3 by bonding the circuit wafer 3 and the array wafer 4 (FIG. 9A). The circuit wafer 3 and the array wafer 4 are bonded such that e.g., the transistors 12, the stacked film 22 and the columnar portions 24 are sandwiched between the substrate 11 and the substrate 26. In the bonding, the metal pads 38 and the metal pads 41 are joined to each other and the inter layer dielectric 13 and the inter layer dielectric 21 are bonded to each other.

Next, the substrate 26 is removed by chemical mechanical polishing (CMP) (FIG. 9B). As a result, the semiconductor layer 24b of each columnar portion 24 is exposed.

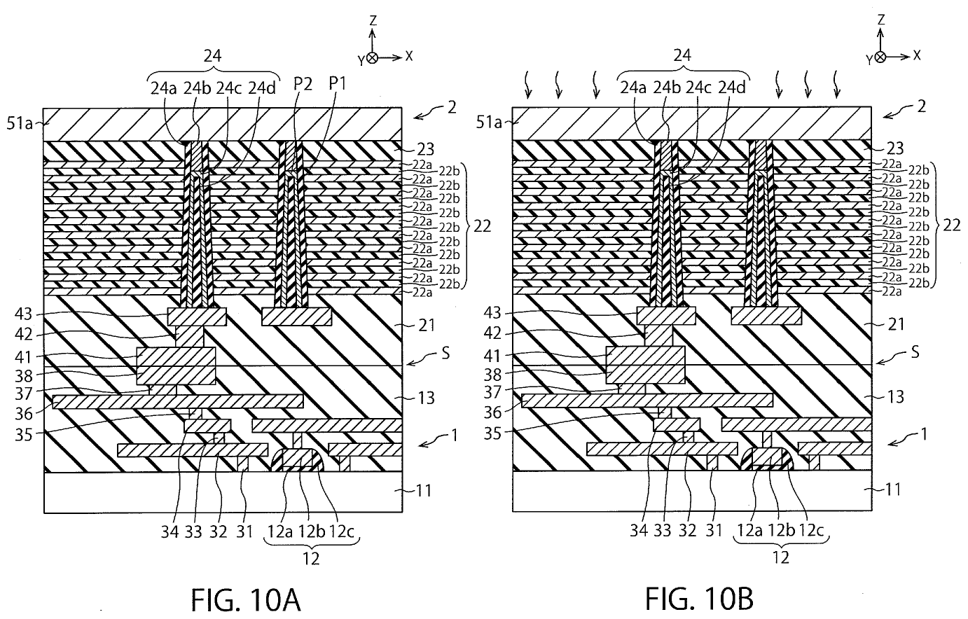

Next, a semiconductor layer 51a of an interconnect layer 51 is formed on the inter layer dielectric 23 and the columnar portions 24 (FIG. 10A). The semiconductor layer 51a formed in the step in FIG. 10A is, for example, a P atom-doped amorphous silicon layer. The semiconductor layer 51a is formed to be in contact with the semiconductor layer 24b of each columnar portion 24, and is thereby electrically connected to the semiconductor layer 24b of each columnar portion 24.

Next, the semiconductor layer 51a is annealed by laser annealing (FIG. 10B). As a result, the semiconductor layer 51a, which is an amorphous silicon layer, turns into a polysilicon layer.

Subsequently, a metal layer 51b of the interconnect layer 51 is formed on the semiconductor layer 51a and a passivation film 52 is formed on the metal layer 51b (see FIG. 1). In this way, the semiconductor device of the present embodiment is manufactured.

When the semiconductor device of the comparative example illustrated in FIG. 4 is manufactured, for example, P atoms are diffused into the channel semiconductor layer 24c from a semiconductor layer 51a by the annealing in the step in FIG. 10B to form the impurity diffusion layer 25 in the channel semiconductor layer 24c. However, in this method, it is difficult to bring positions of impurity diffusion layers 25 in different columnar portions 24 close to a same position. In addition, in order to curb the annealing adversely affecting the metal pads 38, 41, it is desirable to perform the annealing in the step in FIG. 10B in a short time. This is also an obstacle to diffusing P atoms into the channel semiconductor layer 24c from the semiconductor layer 51a.

On the other hand, in the present embodiment, instead of forming the impurity diffusion layer 25 in the channel semiconductor layer 24c, the semiconductor layer 24b is formed separately from the channel semiconductor layer 24c. This makes it possible to solve the problem in the semiconductor device of the comparative example.

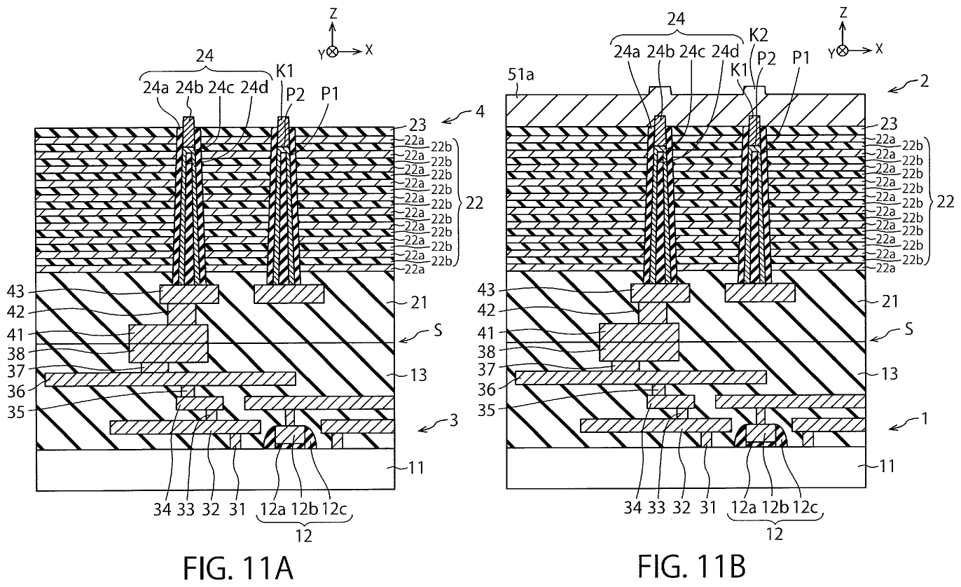

FIGS. 11A and 11B are sectional views illustrating a method of manufacturing a semiconductor device of a modification of the first embodiment.

First, after the steps in FIGS. 5A to 9B are performed, a substrate 26 is removed by wet etching (FIG. 11A). As a result, a semiconductor layer 24b of each columnar portion 24 is exposed. In the step in FIG. 11A, an inter layer dielectric 23 and a memory insulator 24a may partly be removed together with the substrate 26. In this case, as illustrated in FIG. 11A, a portion K1 of the semiconductor layer 24b of each columnar portion 24 projects from the inter layer dielectric 23 and the relevant memory insulator 24a.

Next, as in the step in FIG. 10A, the semiconductor layer 51a of the interconnect layer 51 is formed on the inter layer dielectric 23 and the columnar portions 24 (FIG. 11B). As a result, the semiconductor layer 51a is formed such that a plurality of portions K2 of the semiconductor layer 51a project in the +Z direction. Each of the portions K2 of the semiconductor layer 51a is formed in the +Z-direction of the portion K1 of the semiconductor layer 24b of the corresponding columnar portion 24. In FIG. 11B, the portions K1 project in the semiconductor layer 51a.

Next, after the step in FIG. 10B is performed, a metal layer 51b of the interconnect layer 51 is formed on the semiconductor layer 51a and a passivation film 52 is formed on the metal layer 51b (see FIG. 1). In this way, the semiconductor device of the present modification is manufactured. The structure of the semiconductor device of the present modification is different from the structure of the semiconductor device of the present embodiment in including the portions K1, K2.

As above, each columnar portion 24 of the semiconductor device of the present embodiment includes the semiconductor layer 24b in addition to the channel semiconductor layer 24c. Therefore, the present embodiment makes it possible to enhance performance of the semiconductor layers (the channel semiconductor layer 24c and the semiconductor layer 24b) in each columnar portion 24. For example, the present embodiment makes it possible to easily bring positions of semiconductor layers 24b in different columnar portions 24 close to a same position, which makes it possible to easily bring values of GIDL currents generated in the different columnar portions 24 close to a same value.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
a stacked film including a plurality of electrode layers and a plurality of insulating layers alternately provided above the substrate;
a first semiconductor layer provided in the stacked film;
a second semiconductor layer provided on the first semiconductor layer in the stacked film, and including a monocrystalline semiconductor layer; and
an interconnect layer provided on the stacked film and the second semiconductor layer, and electrically connected to the second semiconductor layer.

2. The device of claim 1, wherein:
the first semiconductor layer has a tubular shape extending in a first direction; and
the second semiconductor layer has a non-tubular shape extending in the first direction.

3. The device of claim 2, wherein:
the first semiconductor layer includes a first portion having a tubular shape extending in the first direction, and a second portion having a bottom shape provided on an upper end of the tubular shape of the first portion; and
the second semiconductor layer has a non-tubular shape extending in the first direction, and is provided on the second portion of the first semiconductor layer.

4. The device of claim 3, further comprising an insulator provided in the first portion of the first semiconductor layer.

5. The device of claim 1, further comprising a charge storage layer having a tubular shape, and surrounding the first semiconductor layer and the second semiconductor layer.

6. The device of claim 1, wherein the first semiconductor layer includes a polycrystalline semiconductor layer.

7. The device of claim 1, wherein the second semiconductor layer includes n-type impurity atoms or p-type impurity atoms.

8. The device of claim 7, wherein a density of the n-type impurity atoms or the p-type impurity atoms in the second semiconductor layer is 1.0×10¹⁹ cm⁻³ or more.

9. The device of claim 1, wherein the interconnect layer includes
a third semiconductor layer provided on the stacked film and the second semiconductor layer, and in contact with the second semiconductor layer; and
a metal layer provided on the third semiconductor layer.

10. The device of claim 9, wherein the second semiconductor layer includes a portion projecting in the third semiconductor layer.

11. The device of claim 1, wherein:
the plurality of electrode layers include one or more first select lines, a plurality of word lines provided above the first select lines, and one or more second select lines provided above the word lines; and
a lower face of the second semiconductor layer is provided at a level that is between a lower face of the lowermost second select line and an upper face of the uppermost second select line.

12. A semiconductor device manufacturing method comprising:
forming a stacked film including a plurality of first films and a plurality of second films alternately, above a first substrate;
forming a concave portion in the stacked film to expose the first substrate in the concave portion;
forming a second semiconductor layer including a monocrystalline semiconductor layer, on the first substrate in the concave portion;
forming a first semiconductor layer on the second semiconductor layer in the concave portion;
bonding the first substrate and a second substrate to sandwich the stacked film, the first semiconductor layer and the second semiconductor layer;
removing the first substrate to expose the second semiconductor layer after bonding the first substrate and the second substrate; and
forming an interconnect layer on the exposed second semiconductor layer to electrically connect the interconnect layer to the second semiconductor layer.

13. The method of claim 12, wherein the second semiconductor layer is formed by epitaxial growth from the first substrate.

14. The method of claim 12, wherein:
the second semiconductor layer is formed to have a non-tubular shape extending in a first direction; and
the first semiconductor layer is formed to have a tubular shape extending in the first direction.

15. The method of claim 14, wherein the first semiconductor layer is formed to include a first portion having a tubular shape extending in the first direction, and a second portion having a bottom shape provided at a lower end of the tubular shape of the first portion.

16. The method of claim 15, further comprising forming an insulator in the first portion of the first semiconductor layer.

17. The method of claim 12, wherein the second semiconductor layer and the first semiconductor layer are formed in the concave portion via a charge storage layer.

18. The method of claim 12, wherein the first semiconductor layer is formed to include a polycrystalline semiconductor layer.

19. The method of claim 12, wherein the second semiconductor layer is formed to include n-type impurity atoms or p-type impurity atoms.

20. The method of claim 19, wherein a density of the n-type impurity atoms or the p-type impurity atoms in the second semiconductor layer is 1.0×10¹⁹ cm⁻³ or more.
